(19) United States
(12) Patent Application Publication
(10) Pub. No.: US 2026/0353899 A1
(43) Pub. Date: Nov. 5, 2026

(54) DISPLAY PANEL AND DISPLAY DEVICE

(71) Applicant: Hefei Visionox Technology Co., Ltd., Hefei (CN)

(72) Inventor: Min ZOU, Hefei (CN)

(73) Assignee: Hefei Visionox Technology Co., Ltd., Hefei (CN)

(21) Appl. No.: 19/719,155

(22) Filed: Jun. 24, 2026

(30) Foreign Application Priority Data
Sep. 28, 2025 (CN) 202511405823.7

(51) Int. Cl. H10H 29/855; H10H 29/37

(52) U.S. Cl. CPC H10H 29/8552; H10H 29/37

(57) ABSTRACT

The present disclosure provides a display panel and a display device. The pixel layer includes a shared pixel region disposed in a shared area and a privacy pixel region disposed in a privacy area. The shared pixel region includes a number of shared sub-pixels arranged along a second direction, and the privacy pixel region includes a number of privacy sub-pixels arranged along the second direction. The privacy layer is disposed on a side of the pixel layer away from the base substrate. The privacy layer includes a light-transmitting region disposed in the shared area and a light-shielding region disposed in the privacy area. The light-shielding region is provided with a plurality of light-transmitting holes arranged along the second direction. At least two of the light-transmitting regions have unequal widths in the first direction, and/or at least two of the light-shielding regions have unequal widths in the first direction, thereby improving uneven brightness and darkness areas such as stripes and lines in a screen-off state, i.e., improving the mura issue of the display panel.

### CROSS-REFERENCE TO RELATED APPLICATION

This application claims priority to Chinese Patent Application No. 202511405823.7 filed Sep. 28, 2025, the disclosure of which is incorporated herein by reference in its entirety.

### FIELD

The present disclosure relates to the field of display technology, and specifically to a display panel and a display device.

### BACKGROUND

With the rapid development of mobile communication device technology and the widespread adoption of smart terminal devices, user demand for privacy protection in display devices is increasingly growing. Privacy screen technology has emerged accordingly, becoming a key configuration for high-end laptops, smartphones, tablets, and public display devices such as ATMs. In one embodiment, a privacy structure is designed on the display panel or module structure to limit the visible range of the screen. When facing the screen, the image is clearly perceived, while when the viewing angle deviates from the screen, the image rapidly dims or disappears, thereby effectively preventing side peeping and protecting user privacy and information security.

In the related art, the display panel is conFIG.d to include a shared area and a privacy area, where the privacy area is shielded by a privacy layer and the shared area is not shielded by the privacy layer, to limit the visible range of the display panel. However, in an off-screen (non-operating) state, the surface of the display panel is prone to areas of uneven brightness and darkness, such as stripes or fine lines, i.e., mura issues occur in the off-screen state, severely affecting user experience.

### SUMMARY

In view of these embodiments, a display panel and a display device are provided to improve the problem of uneven brightness and darkness areas, such as stripes or fine lines, on the surface of the display panel in the off-screen state.

In a first aspect, the present disclosure provides a display panel. The display panel includes a plurality of shared areas and a plurality of privacy areas. The shared areas and the privacy areas are alternately arranged along a first direction. The display panel includes a substrate and a pixel layer. The pixel layer is disposed on one side of the substrate. The pixel layer includes shared pixel regions disposed in the shared areas and privacy pixel regions disposed in the privacy areas. The shared pixel regions include a plurality of shared sub-pixels arranged along a second direction. The privacy pixel regions include a plurality of privacy sub-pixels arranged along the second direction, the second direction intersecting the first direction. The display panel includes a privacy layer disposed on a side of the pixel layer away from the substrate. The privacy layer includes light-transmitting regions disposed in the shared areas and light-shielding regions disposed in the privacy areas. The light-shielding regions are provided with a plurality of light-transmitting holes arranged along the second direction. The orthographic projection of the light-transmitting hole on the pixel layer covers at least a portion of that of a corresponding privacy sub-pixel. At least two light-transmitting regions have unequal widths in the first direction, or, at least two light-shielding regions have unequal widths in the first direction, or, at least two of the light-transmitting regions have unequal widths in the first direction and at least two of the light-shielding regions have unequal widths in the first direction.

In a second aspect, the present disclosure provides a display device, and the display device includes the display panel.

In the display panel of the present disclosure, by disposing the shared pixel region of the pixel layer in the shared region and the light-transmitting region of the privacy layer in the shared region, the emitted light from the shared sub-pixels of the shared pixel region can exit through the light-transmitting region to display an image on the light-emitting side of the display panel. By disposing the privacy pixel region of the pixel layer in the privacy region and the light-shielding region of the privacy layer in the privacy region, a portion of the emitted light from the privacy sub-pixels of the privacy pixel region can be blocked by the light-shielding region, and the emitted light from the privacy sub-pixels has a specific display viewing angle, thereby achieving the privacy function of the display panel. By setting the widths of at least two light-transmitting regions in the first direction to be unequal, or setting the widths of at least two light-shielding regions in the first direction to be unequal, or, setting width of at least two of the light-transmitting regions to be unequal in the first direction and at least two of the light-shielding regions to be unequal in the first direction. The periodic process fluctuations of the privacy layer can be disrupted, thereby improving the issue of uneven brightness areas such as stripes and lines in the screen-off state, i.e., improving the mura problem of the display panel.

### BRIEF DESCRIPTION OF THE DRAWINGS

FIG. 1 is a schematic structural diagram of a privacy layer and a pixel layer of a display panel in the related art.

FIG. 2 is a reflection diagram of the display panel in the related art in a screen-off state.

FIG. 3 is a schematic structural diagram of a privacy layer and a pixel layer of a display panel according to an embodiment of the present disclosure.

FIG. 4 is a partial cross-sectional view of a display panel according to an embodiment of the present disclosure.

FIG. 5 is a light comparison diagram of the display panel in the related art and a display panel according to an embodiment of the present disclosure in a screen-off state.

FIG. 6 is a schematic diagram of brightness of a display panel according to an embodiment of the present disclosure in a screen-off state.

FIG. 7 is a schematic structural diagram of a privacy layer and a pixel layer of a display panel according to another embodiment of the present disclosure.

FIG. 8 is a schematic structural diagram of a privacy layer and a pixel layer of a display panel according to yet another embodiment of the present disclosure.

FIG. 9 is a schematic structural diagram of a privacy layer and a pixel layer of a display panel according to still another embodiment of the present disclosure.

FIG. 10 is a schematic structural diagram of a privacy layer and a pixel layer of a display panel according to still another embodiment of the present disclosure.

FIG. 11 is a schematic structural diagram of a privacy layer and a pixel layer of a display panel according to still another embodiment of the present disclosure.

FIG. 12 is a partial cross-sectional view of a display panel according to still another embodiment of the present disclosure.

FIG. 13 is a partial cross-sectional view of a display panel according to still another embodiment of the present disclosure.

### DETAILED DESCRIPTION

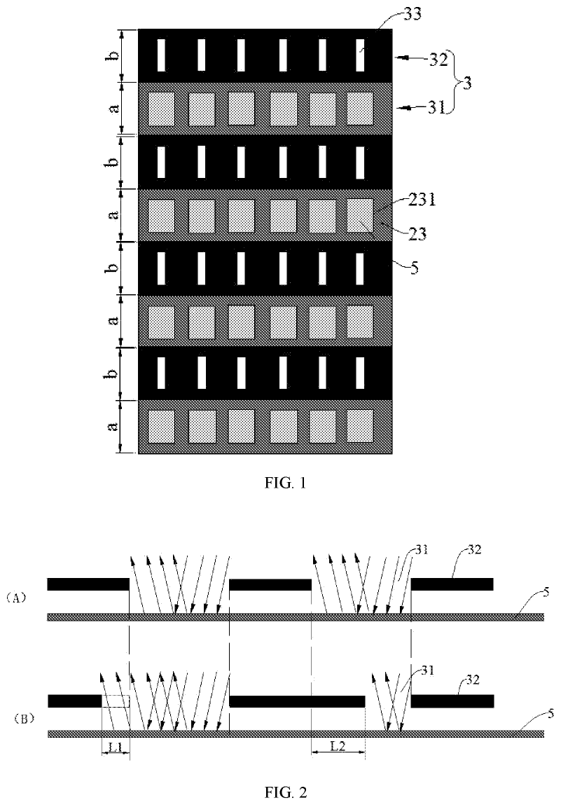

FIG. 1 is a schematic structural diagram of a privacy layer and a pixel layer of a display panel in the related art. FIG. 2 is a reflection diagram of the display panel in the related art in a screen-off state. In the related art, the display panel includes a shared region 101 and a privacy region 102. As shown in FIGS. 1 and 2, the display panel includes a privacy layer 3, which includes a light-transmitting region 31 and a light-shielding region 32. The light-transmitting region 31 is disposed in the shared region 101, and the light-shielding region 32 is disposed in the privacy region 102, and the shared region 101 is not blocked by the privacy layer 3, and the privacy region 102 can be blocked by the privacy layer 3.

To ensure that the image presentation effects of the shared region 101 and the privacy region 102 are similar, the shared region 101 and the privacy region 102 are typically alternately distributed, and the light-transmitting region 31 and the light-shielding region 32 of the privacy layer 3 are also alternately distributed along with the shared region 101 and the privacy region 102. The display panel has film layers with strong reflective capability, such as metal layers. For ease of description and understanding, film layers with strong reflective capability, such as metal layers, are collectively referred to as the reflective layer 5. As shown in FIG. 2, when the display panel is in a screen-off state, light from the outside enters the interior of the display panel. In the privacy region 102, since the light can be blocked by the light-shielding region 32 of the privacy layer 3, the reflective capability is weak; in the shared region 101, since the light is not blocked by the privacy layer 3, the reflective capability is strong.

To ensure that the shared region 101 and the privacy region 102 present alternating bright and dark stripes in the screen-off state, the areas of the privacy region 102 and the shared region 101 are set to be small, making it difficult for the human eye to identify the alternating bright and dark stripes. When the privacy layer 3 is manufactured according to existing designs, the widths of the light-transmitting regions 31 are uniform, the reflective capability for external light is uniform, there is no visual difference, and there are no Mura issues such as bright and dark stripes or bands. However, existing processes inevitably cause process fluctuations, leading to inconsistent widths of the light-transmitting regions 31, inconsistent reflective capability for external light, and the formation of bright and dark stripe or band Mura issues.

In one embodiment, during the manufacturing process of the display panel, it is sensitive to process fluctuations such as alignment accuracy and template manufacturing accuracy. In an embodiment, when the privacy layer 3 is manufactured, local widening or narrowing, as well as slight alignment deviations, can result in local width differences in the shared region 101.

(A) in FIG. 2 is a reflection diagram of the display panel for external light when the display panel adopts the existing design and is manufactured under ideal conditions, and the display panel is in a screen-off state. (B) in FIG. 2 is a reflection diagram of the display panel for external light when the display panel adopts the existing design and the privacy layer 3 is manufactured using existing processes, and the display panel is in a screen-off state. Here, L1 and L2 represent the difference between the width of the light-shielding region 32 caused by the manufacturing process and the designed width, i.e., the magnitude of process fluctuations.

As can be seen from FIG. 2, when the display panel is in a screen-off state, the reflective capability of some shared regions 101 is too strong, leading to a significant difference in reflective capability between the shared region 101 and the privacy region 102, which in turn results in the formation of uneven brightness areas such as stripes and lines in the screen-off state, i.e., the display panel exhibits a mura problem in the screen-off state.

Experimental studies have found that the process fluctuation of the privacy layer 3 typically varies periodically. In an embodiment, the widths of several adjacent light-shielding regions 32 of the privacy layer 3 are generally larger than the designed width, followed by several adjacent light-shielding regions 32 having widths generally smaller than the designed width.

This causes, in the off-screen state, some areas of the display panel to exhibit stronger reflection intensity while other areas exhibit weaker reflection intensity, leading to the formation of strip-like, line-like, or other uneven brightness regions perceptible to the human eye in the off-screen state.

To address the above issue, the present disclosure innovatively designs the privacy layer 3 of the related art. In the related art, all light-shielding regions 32 of the privacy layer 3 have equal designed widths, and all light-transmitting regions 31 of the privacy layer 3 have equal designed widths. This is changed to at least two light-shielding regions 32 having unequal designed widths, or at least two light-transmitting regions 31 having unequal designed widths, or, at least two of the light-transmitting regions having unequal widths in the first direction and at least two of the light-shielding regions having unequal widths in the first direction.

By introducing irregular variations into the privacy layer 3 (at least two light-shielding regions 32 having unequal designed widths, at least two light-transmitting regions 31 having unequal designed widths), the periodically varying process fluctuation of the privacy layer 3 is disrupted, resulting in more consistent widths of the multiple light-transmitting regions 31, thereby improving the issue of forming strip-like, line-like, or other uneven brightness regions in the off-screen state. The embodiments of the present disclosure will be clearly and completely described below with reference to the accompanying drawings of the embodiments of the present disclosure.

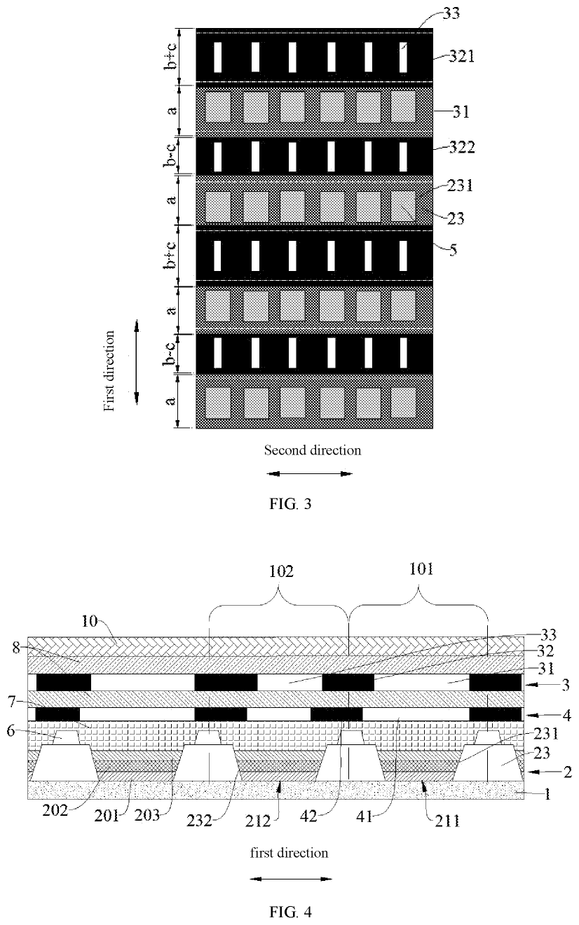

In one embodiment, the described embodiments are only a part of the embodiments of the present disclosure, rather than all of them. FIG. 3 is a schematic structural diagram of the privacy layer 3 and the pixel layer 2 of a display panel provided by an embodiment of the present disclosure.

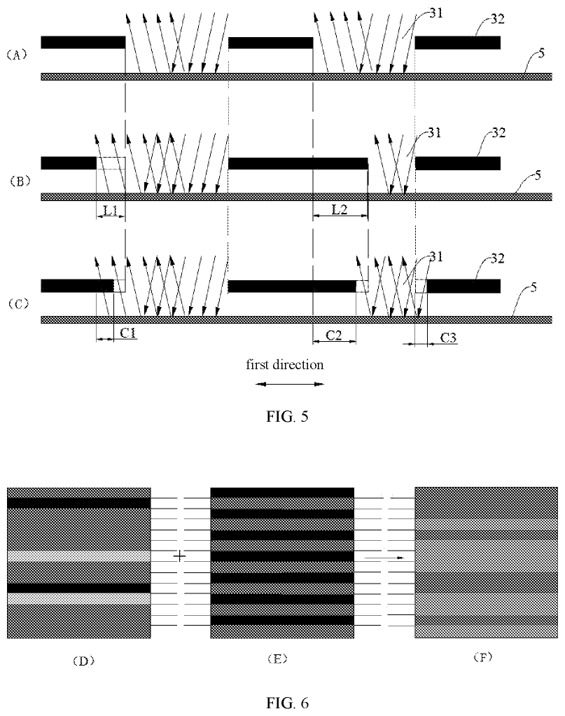

FIG. 4 is a partial cross-sectional view of a display panel provided by an embodiment of the present disclosure. FIG. 5 is a light comparison diagram of a display panel in the off-screen state in the related art and an embodiment of the present disclosure. FIG. 6 is a principle diagram of brightness of a display panel in the off-screen state provided by an embodiment of the present disclosure.

Referring to FIGS. 3 to 6, the display panel includes a plurality of sharing regions 101 and a plurality of privacy regions 102, the sharing regions 101 and the privacy regions 102 being alternately arranged along a first direction. The display panel includes a base substrate 1, a pixel region, and a privacy layer 3. The pixel layer 2 is disposed on one side of the base substrate 1, and the privacy layer 3 is disposed on a side of the pixel layer 2 away from the base substrate 1. The pixel layer 2 includes a sharing pixel region disposed in the sharing region 101 and a privacy pixel region disposed in the privacy region 102. The sharing pixel region includes a plurality of sharing sub-pixels 211 arranged along a second direction, and the privacy pixel region includes a plurality of privacy sub-pixels 212 arranged along the second direction, the second direction intersecting the first direction. The privacy layer 3 includes a light-transmitting region 31 disposed in the sharing region 101 and a light-shielding region 32 disposed in the privacy region 102. The light-shielding region 32 is provided with a plurality of light-transmitting holes 33 arranged along the second direction. An orthographic projection of the light-transmitting hole 33 on the pixel layer 2 covering at least a portion of an orthographic projection of the privacy sub-pixel 212. At least two light-transmitting regions 31 have unequal widths in the first direction, or at least two light-shielding regions 32 have unequal widths in the first direction, or, at least two of the light-transmitting regions have unequal widths in the first direction and at least two of the light-shielding regions have unequal widths in the first direction.

Here, the sharing sub-pixels 211 in the sharing region 101 can be understood as sub-pixels having a normal display viewing angle (e.g., a wide viewing angle), and the light-transmitting region 31 of the privacy layer 3 does not affect the emitted light of the sharing sub-pixels 211. The privacy sub-pixels 212 can be understood as sub-pixels that themselves have a normal display viewing angle (e.g., a wide viewing angle), but the emitted light of the privacy sub-pixels 212 in a specific direction is suppressed by the light-shielding region 32 of the privacy layer 3, thereby giving the emitted light of the privacy sub-pixels 212 a specific display viewing angle.

Here, the orthographic projection of the light-transmitting hole 33 on the pixel layer 2 covering at least a portion of the orthographic projection of the privacy sub-pixel 212 can be understood as: the orthographic projection of the light-transmitting hole 33 on the pixel layer 2 covers the orthographic projection of the entirety of the corresponding privacy sub-pixel 212; or, the orthographic projection of the light-transmitting hole 33 on the pixel layer 2 covers a portion of the orthographic projection of the corresponding privacy sub-pixel 212, and another portion of the privacy sub-pixel 212 is not covered by the orthographic projection of the light-transmitting hole 33 on the pixel layer 2. The portion of the orthographic projection of the privacy sub-pixel 212 covered by the orthographic projection of the light-transmitting hole 33 on the pixel layer 2 allows emitted light to exit through the light-transmitting hole 33.

By providing the light-transmitting holes 33 in the light-shielding region 32, with the orthographic projection of the light-transmitting holes 33 on the pixel layer 2 covering the privacy sub-pixels 212, a portion of the emitted light of the privacy sub-pixels 212 can exit through the light-transmitting holes 33, while another portion of the emitted light of the privacy sub-pixels 212 is blocked by the light-shielding region 32 of the privacy layer 3, thereby giving the emitted light of the privacy sub-pixels 212 a specific display viewing angle. Here, at least two light-transmitting regions 31 having unequal widths in the first direction can be understood as: two of the light-transmitting regions 31 having unequal widths in the first direction; or, more than two light-transmitting regions 31 having unequal widths in the first direction.

At least two light-shielding regions 32 having unequal widths in the first direction can be understood as: two of the light-shielding regions 32 having unequal widths in the first direction; or, more than two light-shielding regions 32 having unequal widths in the first direction. In the display panel of the present disclosure, by disposing the sharing pixel region of the pixel layer 2 in the sharing region 101 and disposing the light-transmitting region 31 of the privacy layer 3 in the sharing region 101, the emitted light of the sharing sub-pixels 211 in the sharing pixel region can exit through the light-transmitting region 31 to display an image on the light-exiting side of the display panel.

By disposing the privacy pixel region of the pixel layer 2 in the privacy region 102 and disposing the light-shielding region 32 of the privacy layer 3 in the privacy region 102, a portion of the emitted light of the privacy sub-pixels 212 in the privacy pixel region can be blocked by the light-shielding portion 42, thereby giving the emitted light of the privacy sub-pixels 212 a specific display viewing angle, achieving the privacy function of the display panel.

By setting the widths of at least two light-transmitting regions 31 in the first direction to be unequal, and/or setting the widths of at least two light-shielding regions 32 in the first direction to be unequal, the periodically varying process fluctuation of the privacy layer 3 can be disrupted, thereby improving the issue of forming strip-like, line-like, or other uneven brightness regions in the off-screen state, i.e., improving the mura issue of the display panel.

In one embodiment, as shown in FIG. 5, (A) in FIG. 5 is a reflection diagram of external light on a display panel when the display panel adopts an existing design and is manufactured under ideal conditions, and the display panel is in a turned-off state. (B) in FIG. 5 is a reflection diagram of external light on a display panel when the display panel adopts an existing design and is manufactured using an existing process, and the display panel is in a turned-off state. Here, L1 and L2 are the differences between the width of the light-shielding region 32 caused by the process and the design width, i.e., the process fluctuation magnitude. (C) in FIG. 5 is a reflection diagram of external light on a display panel when the display panel adopts the design of an embodiment of the present disclosure and is manufactured using an existing process, and the display panel is in a turned-off state.

C1, C2, and C3 in FIG. 5 are compensation values of the privacy layer 3 of the embodiment of the present disclosure manufactured using an existing process, relative to the privacy layer 3 manufactured using an existing design and an existing process. That is, the privacy layer 3 of the embodiment of the present disclosure manufactured using an existing process can effectively compensate for the problem of local widening or narrowing of the light-transmitting region 31 of the privacy layer 3 caused by the process, thereby leading to local narrowing or widening of the light-transmitting region 31 of the privacy layer 3, and improving the problem of uneven brightness and darkness areas such as stripes and lines in the turned-off state.

(D) in FIG. 6 is a brightness diagram of various regions on the light-emitting side of the display panel when the display panel adopts an existing design and is manufactured using an existing process, and the display panel is in a turned-off state. (E) in FIG. 6 is a brightness diagram of various regions on the light-emitting side of the display panel when the display panel adopts the design of an embodiment of the present disclosure and is manufactured under ideal conditions, and the display panel is in a turned-off state. (F) in FIG. 6 is a brightness diagram of various regions of the display panel when the display panel adopts the design of an embodiment of the present disclosure and is manufactured using an existing process, and the display panel is in a turned-off state.

In the FIGs, darker colors indicate darker areas, and lighter colors indicate brighter areas, i.e., from light gray to dark gray to black, gradually becoming darker. As can be seen from FIG. 6, the display panel of the embodiment of the present disclosure can effectively compensate for the problem of local widening or narrowing of the light-transmitting region 31 of the privacy layer 3 caused by the process, thereby leading to local narrowing or widening of the light-transmitting region 31 of the privacy layer 3, and improving the problem of uneven brightness and darkness areas such as stripes and lines in the turned-off state.

Here, the pixel layer 2 includes a plurality of sub-pixels, and sub-pixels disposed in the shared region 101 form shared sub-pixels 211, and sub-pixels disposed in the privacy region 102 form privacy sub-pixels 212. Any metal layer located on the side of the privacy layer 3 close to the base substrate 1 can form the above reflective layer 5. In an embodiment, the metal layer of the pixel layer 2, the metal circuit of the touch layer 9, etc.

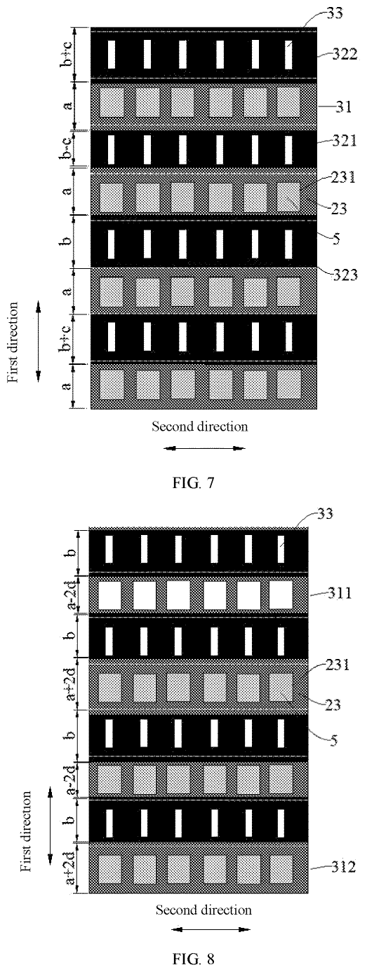

FIG. 7 is a schematic structural diagram of a privacy layer 3 and a pixel layer 2 of a display panel according to another embodiment of the present disclosure. In some embodiments, as shown in FIG. 3 and FIG. 7, the widths of the plurality of light-transmitting regions 31 in the first direction are all equal, and the widths of at least two light-shielding regions 32 in the first direction are not equal. In an embodiment, as shown in FIG. 3 and FIG. 7, the widths of the plurality of light-transmitting regions 31 in the first direction are all a, and the widths of the light-shielding regions 32 in the first direction fluctuate around b. By setting the widths of the plurality of light-transmitting regions 31 in the first direction to be equal, the fabrication of the plurality of light-transmitting regions 31 is facilitated, which is beneficial for reducing the manufacturing cost of the display panel.

In some embodiments, as shown in FIG. 7, at least one light-shielding region 32 is a first light-shielding region 321, and the width of the first light-shielding region 321 in the first direction is a first preset width. At least one light-shielding region 32 is a second light-shielding region 322, and the width of the second light-shielding region 322 in the first direction is a second preset width, the second preset width being greater than the first preset width. In an embodiment, as shown in FIG. 7, the width of the first light-shielding region 321 in the first direction is b+c, i.e., the first preset width is b+c. The width of the second light-shielding region 322 in the first direction is b−c, i.e., the second preset width is b−c. By setting the first light-shielding region 321 and the second light-shielding region 322 to have different sizes as described above, the problem of local narrowing or widening of the light-transmitting region 31 caused by the process can be effectively compensated, improving the problem of uneven brightness and darkness areas such as stripes and lines in the turned-off state. In some embodiments, as shown in FIG. 7, in the first direction, the light-transmitting regions 31 and the light-shielding regions 32 are alternately arranged, and at least one light-transmitting region 31 is disposed between the first light-shielding region 321 and the second light-shielding region 322.

Here, at least one light-transmitting region 31 being disposed between the first light-shielding region 321 and the second light-shielding region 322 can be understood as: one light-transmitting region 31 is disposed between the first light-shielding region 321 and the second light-shielding region 322; or, two light-transmitting regions 31 are disposed between the first light-shielding region 321 and the second light-shielding region 322; or, more than two light-transmitting regions 31 are disposed between the first light-shielding region 321 and the second light-shielding region 322.

As described above, the process fluctuation magnitude of the privacy layer 3 typically varies periodically, i.e., within the same region, the widths of the light-shielding regions 32 are generally larger or smaller than the design width. By disposing the light-transmitting region 31 between the first light-shielding region 321 with a smaller width and the second light-shielding region 322 with a larger width, it is possible to avoid the problem that the design widths of the light-shielding regions 32 in the same region are generally wider or generally narrower, which would not only fail to compensate for the problem of local widening or narrowing of the light-transmitting region 31 of the privacy layer 3 caused by the process, but would even worsen the problem of local widening or narrowing of the light-transmitting region 31.

In an embodiment, when, in a set region, the widths of the light-shielding regions 32 are generally larger than the design width, and the design widths of the light-shielding regions 32 are generally wider, this results in the actually manufactured display panel having, in that set region, all widths of the light-shielding regions 32 being relatively wide, making the problem of local widening of the light-shielding regions 32 more severe. By disposing at least one light-transmitting region 31 between the first light-shielding region 321 and the second light-shielding region 322, the problem of local widening or narrowing of the light-transmitting region 31 of the privacy layer 3 caused by the process can be better compensated, improving the problem of uneven brightness and darkness areas such as stripes and lines in the turned-off state.

In some embodiments, as shown in FIG. 7, at least one light-shielding region 32 is a third light-shielding region 323, and the width of the third light-shielding region 323 in the first direction is a third preset width, the third preset width being greater than the first preset width and less than the second preset width.

In an embodiment, as shown in FIG. 7, the width of the third light-shielding region 323 in the first direction is b, i.e., the third preset width is b. By providing the third light-shielding region 323, and the third preset width of the third light-shielding region 323 is greater than the first preset width and less than the second preset width, the width variation of the light-shielding regions 32 of the privacy layer 3 becomes more complex, making it easier to break the periodic process fluctuations of the privacy layer 3 and improve the issue of uneven brightness areas such as stripes or lines in the off-screen state.

Here, the third preset width may be equal to the design width of the light-shielding region 32 in the prior art. This allows for modifications based on the existing design by only widening the first light-shielding region 321 and reducing the second light-shielding region 322, resulting in minimal changes to the existing design, which is beneficial for saving design and mold costs. In some embodiments, at least two adjacent light-shielding regions 32 are both third light-shielding regions 323.

That is, the widths of at least two adjacent light-shielding regions 32 are both the third preset width, meaning the widths of the adjacent light-shielding regions 32 remain unchanged. Here, at least two adjacent light-shielding regions 32 being both third light-shielding regions 323 can be understood as: two adjacent light-shielding regions 32 are both third light-shielding regions 323; or, more than two adjacent light-shielding regions 32 are all third light-shielding regions 323. By setting at least two adjacent light-shielding regions 32 as third light-shielding regions 323, multiple adjacent third light-shielding regions 323 serve as a transition from periodic variation to irregular variation. Additionally, as described above, the process fluctuations of the privacy layer 3 typically exhibit periodic changes, i.e., within the same region, the widths of the light-shielding regions 32 are generally larger or smaller than the design width.

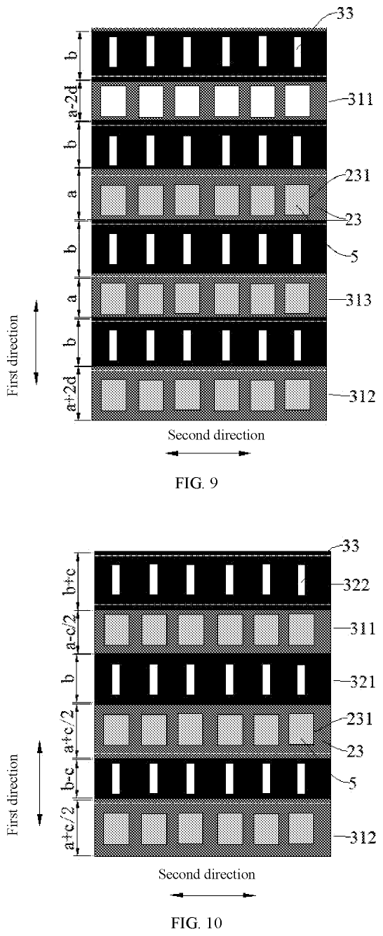

By setting at least two adjacent light-shielding regions 32 as third light-shielding regions 323, the issue of local widening or narrowing of the light-transmitting regions 31 can be prevented from worsening, effectively improving the problem of uneven brightness areas such as stripes or lines in the off-screen state. FIG. 8 is a schematic structural diagram of a privacy layer 3 and a pixel layer 2 of a display panel according to another embodiment of the present disclosure. FIG. 9 is a schematic structural diagram of a privacy layer 3 and a pixel layer 2 of a display panel according to yet another embodiment of the present disclosure.

In some embodiments, as shown in FIGS. 8 and 9, the widths of each light-shielding region 32 in the first direction are all equal, and the widths of at least two light-transmitting regions 31 in the first direction are not equal. In an embodiment, as shown in FIGS. 8 and 9, the widths of multiple light-shielding regions 32 in the first direction are all b, and the widths of the light-transmitting regions 31 in the first direction fluctuate around a. By setting the widths of multiple light-shielding regions 32 in the first direction to be equal, the fabrication of multiple light-shielding regions 32 is facilitated, which is beneficial for reducing the manufacturing cost of the display panel.

In some embodiments, as shown in FIGS. 8 and 9, at least one light-transmitting region 31 is a first light-transmitting region 311, and the width of the first light-transmitting region 311 in the first direction is a first preset dimension. At least one light-transmitting region 31 is a second light-transmitting region 312, and the width of the second light-transmitting region 312 in the first direction is a second preset dimension, where the second preset dimension is greater than the first preset dimension. In an embodiment, as shown in FIGS. 8 and 9, the width of the first light-transmitting region 311 in the first direction is a−2d, i.e., the first preset dimension is a−2d. The width of the second light-transmitting region 312 in the first direction is a+2d, i.e., the second preset dimension is a+2d.

By setting the first light-transmitting region 311 and the second light-transmitting region 312 to have unequal sizes as described, the issue of local widening or narrowing of the light-transmitting regions 31 of the privacy layer 3 due to process manufacturing can be effectively compensated, improving the problem of uneven brightness areas such as stripes or lines in the off-screen state.

In some embodiments, as shown in FIGS. 8 and 9, in the first direction, the light-transmitting regions 31 and the light-shielding regions 32 are alternately arranged, and at least one light-shielding region 32 is disposed between the first light-transmitting region 311 and the second light-transmitting region 312.

Here, at least one light-transmitting region 31 being disposed between the first light-transmitting region 311 and the second light-transmitting region 312 can be understood as: one light-shielding region 32 is disposed between the first light-transmitting region 311 and the second light-transmitting region 312; or, two light-shielding regions 32 are disposed between the first light-transmitting region 311 and the second light-transmitting region 312; or, more than two light-shielding regions 32 are disposed between the first light-transmitting region 311 and the second light-transmitting region 312.

As described above, the process fluctuations of the privacy layer 3 typically exhibit periodic changes, i.e., within the same region, the widths of the light-transmitting regions 31 are generally larger or smaller than the design width. By disposing the light-transmitting regions 31 between the first light-transmitting region 311 with a smaller width and the second light-transmitting region 312 with a larger width, it can be avoided that the design widths of the light-transmitting regions 31 within the same region are generally too wide or too narrow, which would not only fail to compensate for the local widening or narrowing of the light-transmitting regions 31 of the privacy layer 3 due to process manufacturing but could even worsen the issue.

In an embodiment, when in a set region, the widths of the light-transmitting regions 31 are generally greater than the design width, and the design widths of the light-transmitting regions 31 are generally too wide, this results in the actually manufactured display panel having all light-transmitting regions 31 in that set region being too wide, exacerbating the local widening issue. By disposing at least one light-shielding region 32 between the first light-transmitting region 311 and the second light-transmitting region 312, the issue of local widening or narrowing of the light-transmitting regions 31 of the privacy layer 3 due to process manufacturing can be better compensated, improving the problem of uneven brightness areas such as stripes or lines in the off-screen state.

In some embodiments, as shown in FIG. 9, at least one light-transmitting region 31 is a third light-transmitting region 313, and the width of the third light-transmitting region 313 in the first direction is a third preset dimension, where the third preset dimension is greater than the first preset dimension and less than the second preset dimension. In an embodiment, as shown in FIG. 9, the width of the third light-transmitting region 313 in the first direction is a, i.e., the third preset dimension is a. By providing the third light-transmitting region 313, and the third preset dimension of the third light-transmitting region 313 is greater than the first preset dimension and less than the second preset dimension, the width variation of the light-transmitting regions 31 of the privacy layer 3 becomes more complex, making it easier to break the periodic process fluctuations of the privacy layer 3 and improve the issue of uneven brightness areas such as stripes or lines in the off-screen state.

The third preset size may be equal to the design width of the light-transmitting regions 31 in the prior art. This allows for widening of the first light-transmitting regions 311 and reducing the second light-transmitting regions 312 based on the existing design, with minimal changes to the existing design, facilitating cost savings in design and mold costs. In some embodiments, at least two adjacent light-transmitting regions 31 are both third light-transmitting regions 313.

That is, the widths of at least two adjacent light-transmitting regions 31 are both the third preset size, meaning the widths of the adjacent light-transmitting regions 31 remain unchanged. Here, at least two adjacent light-transmitting regions 31 being both third light-transmitting regions 313 can be understood as: two adjacent light-transmitting regions 31 are both third light-transmitting regions 313; or, more than two adjacent light-transmitting regions 31 are both third light-transmitting regions 313. By setting at least two adjacent light-transmitting regions 31 as third light-transmitting regions 313, multiple adjacent third light-transmitting regions 313 serve as a transition from periodic regular changes to irregular changes.

Additionally, as described above, the process fluctuation magnitude of the privacy layer 3 typically varies periodically, meaning that within the same region, the widths of each light-transmitting region 31 are generally larger or smaller than the design width. By setting at least two adjacent light-transmitting regions 31 as third light-transmitting regions 313, the issue of localized widening or narrowing of the light-transmitting regions 31 can be avoided, effectively improving the problem of uneven brightness areas such as stripes or lines in the off-screen state.

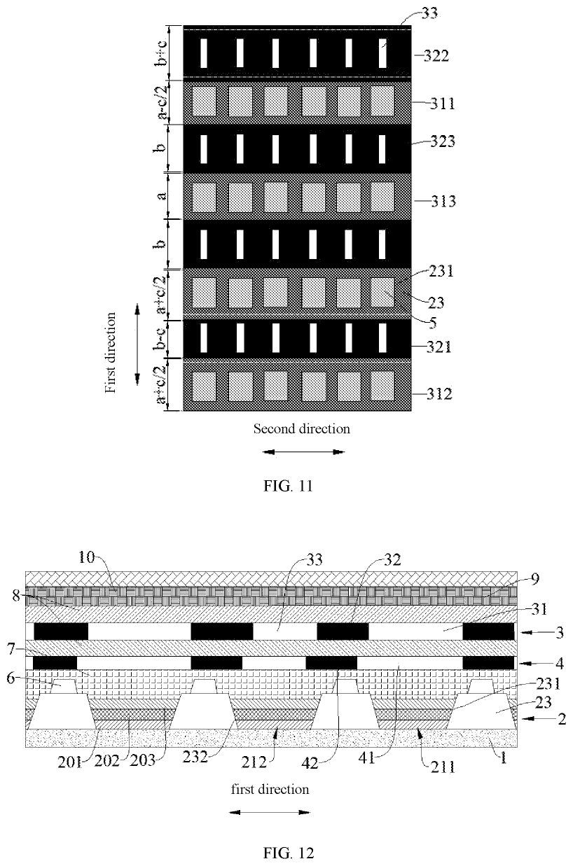

FIG. 10 shows a schematic structural diagram of the privacy layer 3 and the pixel layer 2 of a display panel according to yet another embodiment of the present disclosure. FIG. 11 shows a schematic structural diagram of the privacy layer 3 and the pixel layer 2 of a display panel according to yet another embodiment of the present disclosure.

In some embodiments, as shown in FIGS. 10 and 11, the light-transmitting regions 31 and the light-shielding regions 32 are alternately arranged, with at least two light-transmitting regions 31 having unequal widths in the first direction, and at least two light-shielding regions 32 having unequal widths in the first direction. Here, at least two light-transmitting regions 31 having unequal widths in the first direction can be understood as: two light-transmitting regions 31 having unequal widths in the first direction; or, more than two light-transmitting regions 31 having unequal widths in the first direction. At least two light-shielding regions 32 having unequal widths in the first direction can be understood as: two light-shielding regions 32 having unequal widths in the first direction; or, more than two light-shielding regions 32 having unequal widths in the first direction.

In an embodiment, the widths of at least two light-transmitting regions 31 in the first direction are a−c/2 and a+c/2, respectively, and the widths of at least two light-shielding regions 32 in the first direction are b+c and b−c, respectively. Moreover, the widths of each light-transmitting region 31 fluctuate around a, and the widths of each light-shielding region 32 fluctuate around b.

By setting the widths of at least two light-transmitting regions 31 in the first direction to be unequal, and the widths of at least two light-shielding regions 32 in the first direction to be unequal, the width variation of the light-shielding regions 32 of the privacy layer 3 becomes more complex, making it easier to break the periodic process fluctuation of the privacy layer 3 and improving the problem of uneven brightness areas such as stripes or lines in the off-screen state. Here, the solutions in FIGS. 10 and 11 can be implemented by moving the light-shielding regions 32 or the light-transmitting regions 31 by a preset distance in the first direction based on the existing design.

In an embodiment, in the existing design, the width of the light-shielding region 32 in the first direction is b, and the width of the light-transmitting region 31 in the first direction is a. By moving at least a portion of the light-shielding regions 32 by c, c/2, etc., in the first direction, and simultaneously moving at least a portion of the light-transmitting regions 31 by c, c/2, etc., in the first direction, the solution of the embodiment of the present disclosure is obtained. In some embodiments, at least one adjacent light-transmitting region 31 and at least one adjacent light-shielding region 32 form a privacy unit, and the width of each privacy unit in the first direction is a first preset value.

In an embodiment, as shown in FIG. 10, two adjacent light-transmitting regions 31 and two adjacent light-shielding regions 32 form a privacy unit, and the width of the privacy unit in the first direction is 2a+2b, i.e., the first preset value is 2a+2b. By setting the width of each privacy unit in the first direction to the first preset value, the widths of the privacy units composed of at least one light-transmitting region 31 and at least one light-shielding region 32 are all controlled within the same range, avoiding the introduction of excessive changes that could worsen the issue of localized widening or narrowing of the light-transmitting regions 31.

In some embodiments, as shown in FIGS. 10 and 11, the widths of at least two light-shielding regions 32 in the first direction are a second preset value, and the widths of at least two light-transmitting regions 31 in the first direction are a third preset value. In an embodiment, the widths of at least two light-shielding regions 32 in the first direction are b, i.e., the second preset value is b. The widths of at least two light-transmitting regions 31 in the first direction are a, i.e., the third preset value is a. By setting the widths of at least two light-shielding regions 32 in the first direction to the second preset value and the widths of at least two light-transmitting regions 31 in the first direction to the third preset value, multiple adjacent third light-transmitting regions 313 serve as a transition from periodic regular changes to irregular changes.

Additionally, as described above, the process fluctuation magnitude of the privacy layer 3 typically varies periodically, meaning that within the same region, the widths of each light-transmitting region 31 are generally larger or smaller than the design width. By setting at least two adjacent light-transmitting regions 31 as third light-transmitting regions 313, the issue of localized widening or narrowing of the light-transmitting regions 31 can be avoided, effectively improving the problem of uneven brightness areas such as stripes or lines in the off-screen state. In some embodiments, among adjacent light-shielding regions 32 and light-transmitting regions 31, the width of the light-shielding region 32 in the first direction is the second preset value, and the width of the light-transmitting region 31 in the first direction is the third preset value.

In an embodiment, as shown in FIG. 10, among adjacent light-shielding regions 32 and light-transmitting regions 31, the width of the light-shielding region 32 in the first direction is b, and the width of the light-transmitting region 31 in the first direction is a. In some embodiments, as shown in FIGS. 3 and 7 to 11, two adjacent light-shielding regions 32 are spaced apart in the first direction, and the space between two adjacent light-shielding regions 32 forms a light-transmitting region 31. By forming the light-transmitting region 31 between two adjacent light-shielding regions 32, the structure of the privacy layer 3 is simplified, facilitating the design and fabrication of the privacy layer 3 and helping to reduce the manufacturing cost of the display panel.

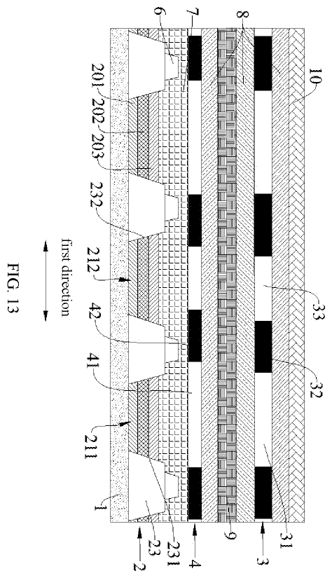

FIG. 12 is a partial cross-sectional view of a display panel according to yet another embodiment of the present disclosure. FIG. 13 is a partial cross-sectional view of a display panel according to yet another embodiment of the present disclosure. In some embodiments, as shown in FIG. 4, FIG. 12, and FIG. 13, the pixel layer 2 includes a pixel definition layer 23, the pixel definition layer 23 is provided with a plurality of first pixel openings 231 and a plurality of second pixel openings 232, at least a portion of the shared sub-pixel 211 is disposed within the first pixel opening 231, and at least a portion of the privacy sub-pixel 212 is disposed within the second pixel opening 232. The dimension of the light-transmitting hole 33 in the first direction is smaller than the dimension of the second pixel opening 232 in the first direction. By setting the dimension of the light-transmitting hole 33 in the first direction to be smaller than the dimension of the second pixel opening 232 in the first direction, it is convenient to control the emitted light of the privacy sub-pixel 212 within a specific display viewing angle, thereby enabling the display panel to have a good privacy function.

In some embodiments, as shown in FIG. 4, FIG. 12, and FIG. 13, the pixel layer 2 includes an anode layer 201, a reflective layer 5, and a cathode layer 223, the anode layer 201 is disposed on a side of the substrate 1 proximate to the pixel definition layer 23, the light-emitting layer 222 is disposed on a side of the anode layer 201 away from the substrate 1, and the cathode layer 223 is disposed on a side of the light-emitting layer 222 away from the substrate 1. The anode layer 201 includes a plurality of anodes arranged in an array, and the anode layer 201 is used to provide holes for absorbing electrons. The light-emitting layer 222 is divided into a plurality of light-emitting units by the pixel definition layer 23, each light-emitting unit corresponds to one anode, and the holes generated by the anode layer 201 absorb the electrons generated by the cathode layer 223 and generate a light source in the light-emitting layer 222. The material of the anode layer 201 may include one or a combination of a metal and a conductive metal oxide; and the metal material may be a metal conductive material such as gold (Au), silver (Ag), copper (Cu), aluminum (Al), and the metal oxide may be a metal oxide conductive material such as indium tin oxide (ITO), indium zinc oxide (IZO), indium gallium zinc oxide (IGZO). The anode layer 201 may be, in one embodiment, patterned by a patterning process, such as a photolithography process or an evaporation process. The material of the cathode layer 223 may be a metal material, such as a metal conductive material with a low work function such as aluminum (Al), silver (Ag), lithium (Li), magnesium (Mg), calcium (Ca), indium (In), to facilitate electron injection; or may be an alloy of a reactive metal such as a magnesium-silver alloy (Mg:Ag) or a lithium-aluminum alloy (Li:Al). The cathode layer 223 may form the above reflective layer 5. An array layer is disposed on the substrate 1, the array layer includes a pixel circuit, the pixel circuit includes a plurality of thin-film transistors, the thin-film transistors include an active layer, a gate layer, and a source-drain layer, and the plurality of thin-film transistors are electrically connected to form a pixel driving circuit arranged in an array.

Each pixel driving circuit corresponds to one sub-pixel to drive the corresponding sub-pixel to emit light for display. In an embodiment, each pixel driving circuit is electrically connected to the anode of the corresponding sub-pixel. The colors of the plurality of sub-pixels may include one, two, three, four, five, or six colors, which is not particularly limited by the present disclosure. Exemplarily, the colors of the plurality of sub-pixels are the same, i.e., the plurality of sub-pixels are used to emit light of the same color. In an embodiment, the plurality of sub-pixels are all used to emit blue light, or the plurality of sub-pixels are all used to emit white light. Exemplarily, the colors of the plurality of sub-pixels are different, in an embodiment, a portion of the sub-pixels are blue sub-pixels (B) for emitting blue light, a portion of the sub-pixels are green sub-pixels (G) for emitting green light, and a portion of the sub-pixels are red sub-pixels (R) for emitting red light. In this case, sub-pixels of different colors can be combined with each other, enabling the display panel to display a color image.

As shown in FIG. 4, FIG. 12, and FIG. 13, the display panel further includes a support column 6, an encapsulation layer 7, and a buffer layer 8, the support column 6 is disposed on a side of the pixel definition layer 23 away from the substrate 1, the encapsulation layer 7 is disposed on a side of the support column 6 away from the substrate 1, and the buffer layer 8 is disposed on at least one side of the privacy layer 3 in the thickness direction of the substrate 1.

As shown in FIG. 4, FIG. 12, and FIG. 13, the display panel further includes a light-shielding layer 4, the light-shielding layer 4 is disposed on a side of the privacy layer 3 proximate to the substrate 1, the light-shielding layer 4 includes a light-transmitting portion 41 and a light-shielding portion 42, the light-transmitting portion 41 is disposed in the shared region 101, the light-shielding portion 42 is disposed in the privacy region 102, and the light-shielding portion 42 is provided with an opening, the orthographic projection of the opening on the pixel layer 2 covers at least a portion of the privacy sub-pixel 212.

In practice, the light-shielding layer 4 can also serve a privacy function, and the combined use of the light-shielding layer 4 and the privacy layer 3 can effectively improve the privacy function of the display panel. As shown in FIG. 12 and FIG. 13, the display panel further includes a touch layer 9, the touch layer 9 may include a touch metal layer, the touch metal layer is provided with touch electrodes and touch traces, and the touch layer 9 is used to implement the touch function of the display panel. The touch layer 9 may be disposed between the privacy layer 3 and the light-shielding layer 4, or may be disposed on a side of the privacy layer 3 away from the substrate 1. When the touch layer 9 is disposed between the privacy layer 3 and the light-shielding layer 4, the metal layer of the touch layer 9 may form the above reflective layer 5. As shown in FIG. 12 and FIG. 13, the display panel may further include an overcoat layer 10 (OC), the overcoat layer 10 is disposed on a side of the touch layer 9 away from the substrate 1. The overcoat layer 10 is used to protect the touch layer 9 and serve a planarization function. The overcoat layer 10 may be a transparent resin layer.

The display panel of the embodiment of the present disclosure, by innovatively designing the widths of the light-shielding region 32 and the light-transmitting region 31 of the privacy layer 3 based on the existing design, breaks the periodic process fluctuations of the privacy layer 3, reduces the reflection difference of different sharing regions 101 in the off-screen state, and effectively improves the problem of uneven brightness and darkness areas such as stripes and lines formed in the off-screen state.

In one embodiment, by irregularly designing the widths of the light-transmitting region 31 and/or the light-shielding region 32 of the privacy layer 3. In an embodiment, some light-transmitting regions 31 have wider widths, some light-transmitting regions 31 have narrower widths, some light-transmitting regions 31 have unchanged widths, some light-shielding regions 32 have wider widths, some light-shielding regions 32 have narrower widths, and some light-shielding regions 32 have unchanged widths, the problem of local widening or narrowing of the light-transmitting region 31 of the privacy layer 3 caused by the manufacturing process, which in turn leads to local narrowing or widening of the light-transmitting region 31 of the privacy layer 3, is effectively compensated, and the problem of uneven brightness and darkness areas such as stripes and lines formed in the off-screen state is improved. Another embodiment of the present disclosure provides a display device, which includes the display panel of any of the above embodiments. The display device can display moving images and still images, and can display text or images.

The display device can be any electronic product with a display function, in an embodiment, the display device can be a mobile phone, a watch, a tablet computer, a laptop computer, a television, a digital camera, a smart bracelet, smart glasses, a vehicle display, an industrial control device, etc., and the embodiment of the present disclosure does not impose specific limitations on this. The shape of the display panel can be designed as needed, in an embodiment, it can be a regular shape such as a rectangle, a circle, an ellipse, a diamond, an ellipse, or an irregular shape. The above is only a preferred embodiment of the present disclosure and is not intended to limit the present disclosure. Any modifications, equivalent substitutions, etc., made within the spirit and principle of the present disclosure shall be included in the protection scope of the present disclosure.

1. A display panel, comprising a plurality of shared areas and a plurality of privacy areas, the shared areas and the privacy areas being alternately arranged along a first direction, the display panel comprising:
a base substrate;
a pixel layer, disposed on one side of the base substrate, the pixel layer comprising a shared pixel region disposed in the shared area and a privacy pixel region disposed in the privacy area, the shared pixel region comprising a plurality of shared sub-pixels arranged along a second direction, the privacy pixel region comprising a plurality of privacy sub-pixels arranged along the second direction, the second direction intersecting with the first direction;
a privacy layer, disposed on a side of the pixel layer away from the base substrate, the privacy layer comprising a light-transmitting region disposed in the shared area and a light-shielding region disposed in the privacy area, the light-shielding region being provided with a plurality of light-transmitting holes arranged along the second direction, an orthographic projection of one of the light-transmitting holes on the pixel layer covering an orthographic projection of at least a portion of a corresponding one of the privacy sub-pixels;
wherein,
at least two of the light-transmitting regions have unequal widths in the first direction,
or, at least two of the light-shielding regions have unequal widths in the first direction,
or, at least two of the light-transmitting regions have unequal widths in the first direction and at least two of the light-shielding regions have unequal widths in the first direction.

2. The display panel according to claim 1, wherein the widths of the plurality of light-transmitting regions in the first direction are all equal, and at least two of the light-shielding regions have unequal widths in the first direction.

3. The display panel according to claim 2, wherein at least one of the light-shielding regions is a first light-shielding region, the width of the first light-shielding region in the first direction being a first preset width;
at least one of the light-shielding regions is a second light-shielding region, the width of the second light-shielding region in the first direction being a second preset width, the second preset width being greater than the first preset width.

4. The display panel according to claim 3, wherein in the first direction, the light-transmitting regions and the light-shielding regions are alternately arranged, and at least one of the light-transmitting regions is disposed between the first light-shielding region and the second light-shielding region.

5. The display panel according to claim 3, wherein at least one of the light-shielding regions is a third light-shielding region, the width of the third light-shielding region in the first direction being a third preset width, the third preset width being greater than the first preset width and less than the second preset width.

6. The display panel according to claim 5, wherein at least two adjacent light-shielding regions are both the third light-shielding region.

7. The display panel according to claim 1, wherein the widths of all of the light-shielding regions in the first direction are equal, and at least two of the light-transmitting regions have unequal widths in the first direction.

8. The display panel according to claim 7, wherein that at least one of the light-transmitting regions is a first light-transmitting region, the width of the first light-transmitting region in the first direction being a first preset dimension;
at least one of the light-transmitting regions is a second light-transmitting region, the width of the second light-transmitting region in the first direction being a second preset dimension, the second preset dimension being greater than the first preset dimension.

9. The display panel according to claim 8, in the first direction, the light-transmitting regions and the light-shielding regions are alternately arranged, and at least one of the light-shielding regions is disposed between the first light-transmitting region and the second light-transmitting region.

10. The display panel according to claim 9, wherein at least one of the light-transmitting regions is a third light-transmitting region, the width of the third light-transmitting region in the first direction being a third preset dimension, the third preset dimension being greater than the first preset dimension and less than the second preset dimension.

11. The display panel according to claim 10, at least two adjacent light-transmitting regions are both the third light-transmitting region.

12. The display panel according to claim 1, wherein that the light-transmitting regions and the light-shielding regions are alternately arranged, at least two of the light-transmitting regions have unequal widths in the first direction, and at least two of the light-shielding regions have unequal widths in the first direction.

13. The display panel according to claim 1, wherein at least one light-transmitting region and at least one adjacent light-shielding region form a privacy unit, and the width of each privacy unit in the first direction is a first preset value.

14. The display panel according to claim 1, wherein a width of at least two of the light-shielding regions in the first direction is a second preset value, and
a width of at least two of the light-transmitting regions in the first direction is a third preset value.

15. The display panel according to claim 1, wherein, in the adjacent light-shielding region and light-transmitting region, the width of the light-shielding region in the first direction is a second preset value, and the width of the light-transmitting region in the first direction is a third preset value.

16. The display panel according to claim 1, wherein two adjacent light-shielding regions are spaced apart along the first direction, and the light-transmitting region is enclosed between two adjacent light-shielding regions.

17. The display panel according to claim 1, wherein the pixel layer comprises a pixel definition layer, the pixel definition layer is provided with a plurality of first pixel openings and a plurality of second pixel openings, at least a portion of the shared sub-pixels is disposed within the first pixel openings, at least a portion of the privacy sub-pixels is disposed within the second pixel openings, and the dimension of the light-transmitting hole in the first direction is smaller than the dimension of the second pixel openings in the first direction.

18. A display device, wherein that it comprises the display panel according to claim 1.
